(19) United States
(12) Patent Application Publication
(10) Pub. No.: US 2022/0406894 A1
(43) Pub. Date: Dec. 22, 2022

(54) Semiconductor Devices and Methods of Making Same

(71) Applicant: Georgia Tech Research Corporation, Atlanta (GA)

(72) Inventors: Russell Dean Dupuis, Atlanta, GA (US); Theeradetch Detchprohm, Atlanta, GA (US); Frank Mehnke, Atanta, GA (US); Shyh-Chiang Shen, Atlanta, GA (US)

(21) Appl. No.: 17/806,173

(22) Filed: Jun. 9, 2022

Related U.S. Application Data
(60) Provisional application No. 63/208,653, filed on Jun. 9, 2021.

(51) Int. Cl. H01L 29/15; H01L 29/20; H01L 29/205; H01L 21/02

(52) U.S. Cl. CPC H01L 29/155; H01L 29/2003; H01L 29/205; H01L 21/0254; H01L 21/02458

(57) ABSTRACT

An exemplary embodiment of the present disclosure provides a method of fabricating a semiconductor device, comprising: providing a substrate, the substate comprising a base layer and two or more planar heteroepitaxial layers deposited on the base layer, the two or more heteroepitaxial layers comprising a first epitaxial layer having a first lattice constant and a second epitaxial layer having a second lattice constant different than the first lattice constant; etching the substrate to form one or more mesas; and depositing one or more non-planar overgrowth layers on the etched substrate.

### CROSS-REFERENCE TO RELATED APPLICATIONS

This application claims the benefit of U.S. Provisional Application Ser. No. 63/208,653, filed on 9 Jun. 2021, which is incorporated herein by reference in its entirety as if fully set forth below.

### FIELD OF THE DISCLOSURE

The various embodiments of the present disclosure relate generally to semiconductors and methods of fabricating semiconductors.

### BACKGROUND

Tensile strain limits the epitaxial growth of a wide range of heteroepitaxial films beyond the critical layer thickness (CLT) for many of the III-V compound and other semiconductor material systems. This is especially true for the highly mismatched AlInGaN alloy system. The intrinsic lattice mismatch limits the growth of thick films of high Al mole fraction AlGaN on GaN that is used in a variety of device structures, e.g., ultraviolet (UV) heterostructure laser diodes, advanced UV avalanche photodiodes, and wider-bandgap high-power rectifiers. For layers under tensile strain, growth thicknesses beyond the critical layer thickness result in cracking which inhibits device fabrication.

The CLT for the III-N wurtzite system has been studied by many authors in the past. Of particular interest has been the AlₓGa₁₋ₓN/GaN ternary alloy system and AlₓIn_{y}Ga_{1-x-y}N quaternary system, especially for wider-bandgap devices that require relatively thick films having t>1 μm and where the Al mole fraction, x, exceeds x ˜0.1, e.g., the cladding layers for multiple-quantum-well (MQW) UV laser diodes (LDs). Recently, a theoretical model has been developed for the entire III-N system and compared with earlier experimental data. Experimentally, the CLT (as evidenced by surface crack formation) has been studied for a variety of AlₓGa₁₋ₓN films grown on GaN by Metalorganic chemical vapor deposition (MOCVD) and Molecular beam epitaxy (MBE). The CLT for Al_{0.17}Ga_{0.83}N films grown on (0001) GaN/sapphire has been reported to be ˜100 nm, ˜120 nm, and ˜620 nm, and the CLT for Al_{0.21}Ga_{0.79}N grown on (0001) GaN/sapphire has been reported to be ˜60 nm, ˜70 nm, and ˜200 nm. This wide variation in reported values could be dependent upon the specific buffer layer and growth conditions employed. We also note that these results are obtained for AlₓGa₁₋ₓN films grown on GaN/sapphire substrates and results for growth on free-standing and bulk GaN substrates could be different.

In order to overcome these limitations, much work has been done to explore various selective-area or limited-area semiconductor heteroepitaxial growth processes, particularly for the III-V materials and alloys. Among these are selective-area growth (SAG) and epitaxial lateral overgrowth (ELO) of III-N material. Another related approach that has been used for III-N heteroepitaxy is facet-controlled ELO (FACELO) that has been used for defect reduction and lattice mismatch mitigation for the growth of III-N near UV laser diodes at ˜360 nm with an Al_{0.20}Ga_{0.80}N contact layer on GaN/sapphire templates. In another approach, the coalescence of laterally grown AlₓGa₁₋ₓN (x˜0.26) 15 μm thick films deposited on mask-free GaN etched stripes was used to reduce dislocation density through dislocation annihilation. However, in general, relatively thick epitaxial films are necessary for these approaches to function optimally. Accordingly, there is a need for improved methods allowing for increased thickness of epitaxial films.

### BRIEF SUMMARY

An aspect of the present disclosure provides a method of fabricating a semiconductor device, and in particular a crystalline semiconductor device. The method can comprise: providing a substrate, the substate comprising a base layer and two or more planar heteroepitaxial layers deposited on the base layer, the two or more heteroepitaxial layers comprising a first epitaxial layer having a first lattice constant and a second epitaxial layer having a second lattice constant different than the first lattice constant; etching the substrate to form one or more mesas; and depositing one or more non-planar overgrowth layers on the etched substrate.

In any of the embodiments disclosed herein, the base layer of the substrate can have a nominal offcut angle of between about 0.0 and ±4.0 degrees.

In any of the embodiments disclosed herein, the base layer can comprise sapphire or other suitable crystalline material.

In any of the embodiments disclosed herein, the two or more heteroepitaxial layers can comprise III-V semiconductor materials, or other semiconductors.

In any of the embodiments disclosed herein, the two or more heteroepitaxial layers can comprise GaN.

In any of the embodiments disclosed herein, providing the substrate can comprise: providing the base layer; and epitaxially growing the two or more planar or non-planar heteroepitaxial layers on the base layer.

In any of the embodiments disclosed herein, etching the substrate to form the one or more mesas can comprise: depositing a mask over the substrate; patterning the mask to remove portions of the mask using photolithography; and etching the non-masked portions of the substrate to form the one or more mesas.

In any of the embodiments disclosed herein, the one or more mesas can comprise at least a first mesa having a length to width ratio of between 1:1 and 500:1.

In any of the embodiments disclosed herein, depositing the one or more non-planar overgrowth layers can decrease a tensile strain on the two or more heteroepitaxial layers.

In any of the embodiments disclosed herein, the one or more non-planar overgrowth layers can be epitaxially grown.

In any of the embodiments disclosed herein, the one or more non-planar overgrowth layers can be superlattices.

In any of the embodiments disclosed herein, the one or more non-planar overgrowth layers can comprise one or more materials having the formula of AlₓGa₁₋ₓN.

In any of the embodiments disclosed herein, the one or more non-planar overgrowth layers can comprise a first overgrowth layer comprising a first alloy and a second overgrowth layer comprising a second alloy.

Another aspect of the present disclosure provides a semiconductor device. The semiconductor device can comprise a substrate, one or more mesas formed on the substrate, and one or more non-planar overgrowth layers deposited over the substrate. The substrate can comprise a base layer and two or more heteroepitaxial layers over the base layer. The one or more non-planar overgrowth layers can be deposited over the substrate.

These and other aspects of the present disclosure are described in the Detailed Description below and the accompanying drawings. Other aspects and features of embodiments will become apparent to those of ordinary skill in the art upon reviewing the following description of specific, exemplary embodiments in concert with the drawings. While features of the present disclosure may be discussed relative to certain embodiments and figures, all embodiments of the present disclosure can include one or more of the features discussed herein. Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF THE DRAWINGS

The following detailed description of specific embodiments of the disclosure will be better understood when read in conjunction with the appended drawings. For the purpose of illustrating the disclosure, specific embodiments are shown in the drawings. It should be understood, however, that the disclosure is not limited to the precise arrangements and instrumentalities of the embodiments shown in the drawings.

FIGS. 1A-B provide a top view optical microscopy image and an SEM image under 45 degree tilt angle, respectively, of etched mesa structures with dimensions l=2 mm, w=10 g=50 μm, and d=2.7 μm, in accordance with some embodiments of the present disclosure.

FIGS. 2A-B provide a top view light microscopy image and SEM image under 65° tilt angle, respectively, of a 1500 nm thick NPG Al_{0.16}Ga_{0.84}N-SL on etched mesa structures with dimensions l=2 mm, w=50 μm, g=50 μm, and d=2.7 μm, in accordance with some embodiments of the present disclosure.

FIGS. 3A-C provide XRD reciprocal space maps near the (10-15)_{GaN} reflex for AlGaN-SLs with average composition of x̅₁=0.11 (FIG. 3A), x̅₂=0.16 (FIG. 3B), and x̅₃=0.21 (FIG. 3C), in which near vertical lines represent lattice positions of different percentages of strain release (0%, 25%, 50%, 75%, and 100% relaxation), and in which the diagonal lines (top left to bottom right) represent positions of equal composition, in accordance with some embodiments of the present disclosure.

FIG. 4A provides room temperature mean cathodoluminescence spectrum of NPG Al_{0.16}Ga_{0.84}N-SL over an entire mesa with dimension l=2 mm, w=100 μm, g=100 μm, and d=2.7 μm, in accordance with some embodiments of the present disclosure. FIGS. 4B-C provide monochromatic CL intensity images of the same mesa at a fixed wavelength of 331 nm (FIG. 4B) and 340 nm (FIG. 4C) allowing the identification of the local origin of the different wavelength contributions.

FIG. 5 illustrates the application of non-planar overgrowth layers of AlₓGa₁₋ₓN on patterned GaN/sapphire substrate, which leads to the formation of a c-facet, in accordance with some embodiments of the present disclosure.

FIGS. 6A-C provide spot mode cathodoluminescence spectra at room temperature of non-planar overgrowth AlₓGa₁₋ₓN superlattices with average composition of x̅₁=0.11 (FIG. 6A), x̅₂=0.16 (FIG. 6B), and x̅₃=0.21 (FIG. 6C) on mesa structures with dimensions l=2 mm, w=200 μm, g=100 μm, and d=2.7 μm, in accordance with some embodiments of the present disclosure, measured at the c-facet, the offcut c-plane surface as provided by the sapphire substrate, and at the semipolar sidewalls.

FIG. 7A provides CL spectra at room temperature of an non-planar overgrowth MQW heterostructure on a mesa structure with dimensions l=2 mm, w=50 μm, g=100 μm, and d=2.7 μm, in accordance with some embodiments of the present disclosure. FIGS. 7B-D provide monochromatic CL maps at 345.7 nm (FIG. 7B), 359.3 nm (FIG. 7C), and 373.6 nm (FIG. 7D) indicating homogeneous MQW emission from the mesa surface.

FIG. 8 provides an optical microscopy image of a full NPG laser diode heterostructure grown on a mesa with dimensions l=2 mm, w=30 μm, g=100 μm, and d=2.7 μm, wherein the total thickness of the heterostructure is -1.5 μm, in accordance with some embodiments of the present disclosure.

FIGS. 9A-B provide a V-I plot and 300 K injection-current-dependent EL spectra, respectively, of the edge emission of a 30 μm wide NPG/GaN/sapphire LD stripe for DC drive currents: 5 mA, 10 mA, 15 mA, 20 mA and 25 mA, in accordance with some embodiments of the present disclosure.

### DETAILED DESCRIPTION

To facilitate an understanding of the principles and features of the present disclosure, various illustrative embodiments are explained below. The components, steps, and materials described hereinafter as making up various elements of the embodiments disclosed herein are intended to be illustrative and not restrictive. Many suitable components, steps, and materials that would perform the same or similar functions as the components, steps, and materials described herein are intended to be embraced within the scope of the disclosure. Such other components, steps, and materials not described herein can include, but are not limited to, similar components or steps that are developed after development of the embodiments disclosed herein.

The present disclosure provides processes for fabricating semiconductor materials that expand the limits of heteroepitaxial growth to beyond the limits of the conventional CLT. Some embodiments disclosed herein can use a three-dimensional epitaxial growth process that employs non-planar growth (NPG) structures allowing for lateral strain relaxation and the mitigation of cracking by strain accommodation along one direction. These processes can be performed without growth masks or growth on tilted or “alternate planes” besides the conventional c-plane or (100) plane. These processes can also be performed without unusually thick epitaxial structures beyond that required for the device design. As a practical example described in detail below, the processes disclosed herein have been used to grow quantum-well (QW) laser diode (LD) heterostructures designed for ˜370 nm operation on patterned GaN/sapphire.

An aspect of the present disclosure provides a method of fabricating a semiconductor device. The method can comprise providing a substrate. The substrate can comprise many different materials or combinations of materials. In some embodiments, the substate can comprise a single crystal or one or more crystalline materials. In some embodiments the substrate can comprise one or more layers of materials. In some embodiments, the substrate can comprise a base layer. The base layer can comprise many materials known in the art. In some embodiments, the base layer can comprise sapphire, gallium nitride, aluminum nitride, gallium arsenide, indium phosphide, silicon, other semiconductors, or combinations thereof.

In some embodiments, the substrate can further comprise one or more layers deposited on the base layer. In some embodiments, the substrate can comprise two or more layers deposited on the base layer. In some embodiments, the two or more layers deposited on the base layer can be heteroepitaxial layers. The two or more layers can comprise a first epitaxial layer having a first lattice constant and a second epitaxial layer having a second lattice constant different than the first lattice constant. In some embodiments the two or more epitaxial layers can comprise III-V semiconductor materials. In some embodiments, the two or more epitaxial layers can comprise GaN, AlGaN, AlInGaN, BN, InGaAs, AlInGaAs, AlInGaP, the like, or combinations thereof.

In some embodiments, the substrate can be provided by epitaxially growing two of more planar hetero epitaxial layers on the base layer (e.g., sapphire base layer).

In some embodiments, the substrate can have a nominal offcut angle. The offcut angle can be many different offcut angles. In some embodiments, the offcut angle is between about 0.0 and ±4.0 degrees in one or more crystalline directions.

The method can further comprise etching the substrate to form the one or more mesas. The mesas can be formed by mean methods known in the art. In some embodiments, the mesas can be formed by photolithography. For example, in some embodiments, the mesas can be formed by depositing a mask over the substrate, patterning the mask to remove portions of the mask using photolithography, and etching the non-masked portions of the substrate to form the one or more mesas.

The mesas can have many different dimensions and shapes (e.g., square, triangular, circular, or non-geometrically-shaped) in accordance with desired applications of the semiconductor. In some embodiments, the mesas can be rectangular-shaped and can have a length and width. In some embodiments, the mesas can have a length to width ratio of between 1:1 and 500:1. In some embodiments, the mesas can comprise an isolated surface area surrounded by trenches or stripes with trenches from one edge to another edge of a single crystal substrate.

The method can further comprise depositing one or more non-planar overgrowth layers over the heteroepitaxial layers. The non-planar overgrowth layers can decrease a tensile strain on the two or more heteroepitaxial layers and thus increase a CLT thereof. The non-planar overgrowth layers can comprise many different materials in accordance with various embodiments. In some embodiments, the non-planar overgrowth layers comprise a first layer comprising a first material and a second layer comprising a second material. In some embodiments, the one or more non-planar overgrowth layers can be superlattices. In some embodiments, the one or more non-planar overgrowth layers can comprise one or more materials having the formula of AₓGa₁₋ₓN, AlₓGa₁₋ₓN, AlₓIn_{y}Ga_{1-x-y}N, BₓA₁₋ₓN, BₓAl_{y}Ga_{1-x-y}N, or other semiconductors. In some embodiments, the non-planar overgrowth layers comprise a first layer comprising a first alloy and a second layer comprising a second alloy. The non-planar overgrowth layers can be deposited over the substrate by many different methods known in the art. In some embodiments, the non-planar overgrowth layers can be epitaxially grown.

Another aspect of the present disclosure provides semiconductors made using the processes disclosed herein. The semiconductors can have many different applications. In some embodiments, the semiconductor can be a laser diode, a transistor, a light-emitting diode, a transistor laser, a photodiode, a light-emitting transistor, a rectifier, photonic integrated circuit, or other electronic or optoelectronic device.

The following examples further illustrate aspects of the present disclosure. However, they are in no way a limitation of the teachings or disclosure of the present disclosure as set forth herein.

### EXAMPLES

Fabrication

Heteroepitaxial layers of undoped GaN were deposited on [0001] oriented sapphire substrates with a nominal offcut angle of 0.25° towards the [1-100]ₛₐₚₚₕᵢᵣₑ direction using MOCVD technique in an AIXTRON 6×2″ close-coupled showerhead reactor. Trimethylgallium (TMGa) and ammonia (NH₃) were used as precursors as well as hydrogen (H₂) as carrier gas. The GaN layer thickness as determined by in-situ white light interferometry was 2.7 μm. The threading dislocation density (TDD) of these films was estimated by X-ray diffraction (XRD) to be in the 2×10⁹ cm⁻² range.

Subsequently, these GaN/sapphire templates were patterned using a SiO₂ mask for mesa etching. Prior to the etching process, the wafer was cleaned in piranha solution (4:1 concentrated sulfuric acid:30 wt. % hydrogen peroxide solution) and buffered oxide etchant (BOE). A 600 nm SiO₂ film was deposited on the GaN/sapphire template surface by plasma-enhanced chemical vapor deposition (PECVD) using silane (SiH₄) and nitrous oxide (N₂O) as precursors. Rectangular patterns of length l=2 mm and widths of w=10 μm, 20 μm, 50 μm, 100 μm, and 200 μm were formed by photolithography. Additionally, gap dimensions between the mesas of g=10 μm, 20 μm, 50 μm, 100 μm, and 200 μm were realized. The orientation of the 2 mm long stripes was chosen to be along the [1-100]_{GaN} direction in order to enable {1-100} GaN facets after cleaving. Positive photoresists SC 1827 was used as the SiO₂ etch mask. SiO₂ dry etching was performed by reactive ion etching (RIE) with trifluoromethane (CHF₃) and oxygen (O₂). The wafer was then dipped in piranha solution to remove the photoresist mask.

Consequently, inductively-coupled plasma reactive ion etching (ICP-RIE) was used to etch the non-masked GaN material. The plasma etching conditions were optimized in order to allow for nearly vertical side walls as well as a fast etch rates of ˜6.8 nm/s using 45 sccm of chlorine (Cl₂), 5 sccm of boron trichloride (BCl₃), and 32.5 sccm of helium (He), while the coil and platen power are set to 600 W and 60 W, respectively, at a chamber pressure of 5 mTorr. The etch time of the mesa structures was chosen to achieve etch depths of d=500 nm, 1500 nm, and 3000 nm, i.e., the etched trenches reached the sapphire substrate for the longest etch time as the thickness of the planar GaN layer on the sapphire substrate is only 2.7 After the ICP process, the SiO₂ mask was removed by etching in buffered oxide etchant (BOE) for 10 min.

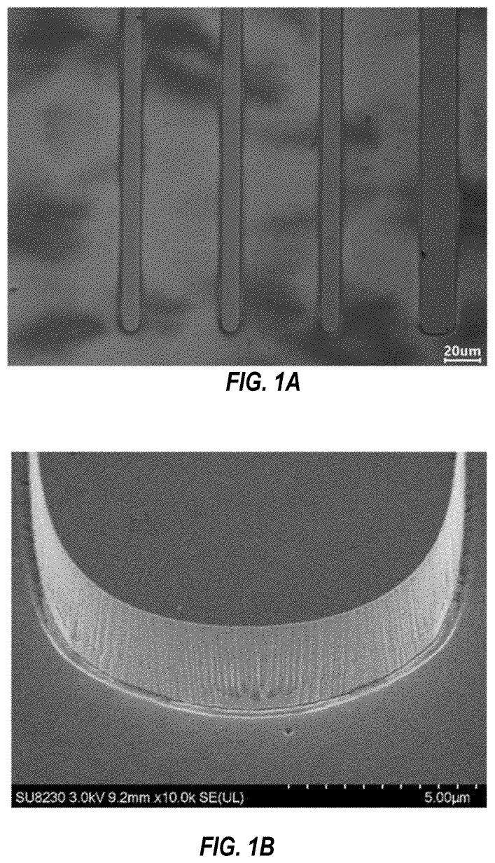

An optical microscopy image using differential interference contrast and a secondary electron microscopy (SEM) image with 45° tilt angle of the etched surface after SiO₂ removal are shown in FIG. 1A-B, respectively. The side walls of the etched GaN mesa were nearly vertical with no visible crystallographic facets on the GaN side walls. Atomic force microscopy (AFM) images of the mesa surface showed no signs of damage and a root-mean-square (RMS) roughness over a 5 μm×5 μm area of ˜0.6 nm. Additionally, small pits were visible in the etched trench regions with a density of approximately 1×10⁶ cm⁻². Most likely, these pits were already within the sapphire due to over-etching and are not existent for shallow etching depths of d=500 nm and d=1500 nm. However, ICP etching of the GaN/sapphire layers does produce pits in the GaN surface as well.

Non-planar overgrowth (NPG) of various AlₓGa₁₋ₓN superlattices (SLs), MQWs, and LD heterostructures on the patterned GaN/sapphire templates was performed by MOCVD using trimethylaluminum (TMAl), TMGa, NH₃ and H₂ as carrier gas. Following a 200 nm thick homoepitaxial GaN buffer layer, AlₓGa₁₋ₓN/Al_{y}Ga_{1-y}N superlattices were deposited at a reactor pressure of 75 Torr using a total flow of 20 slm and a NH₃ partial pressure of 2500 Pa, a TMGa partial pressure of 0.643 Pa, and varying the TMAl partial pressure between 0.028 Pa and 0.246 Pa. In a first approach (sample series 1) the critical layer thickness of the NPG structures was tested by iteratively overgrowing 500 nm of AlₓGa₁₋ₓN/Al_{y}Ga_{1-y}N SLs with x₁/y₁=0.06/0.16, x₂/y₂=0.11/0.21, and x₃/y₃=0.16/0.26 (in the following discussions, the average SL compositions of x̅₁=0.11, x̅₂=0.16, and x̅₃=0.21 will be used) up to crack formation. The periodicity of each SL was 5 nm. Growth was performed on quarters of 2″ diameter patterned GaN/sapphire template wafers. After evaluating the iterative overgrowth experiments of sample series 1, a sample series 2 was grown using the same mesa dimensions but keeping the mesa etch depth constant at d=2700 nm (etch time chosen for 3000 nm) and the total overgrowth thickness constant at 1500 nm using a single continuous growth process. For sample series 2, SL structures with average compositions of x̅₁=0.11, x̅₂=0.16, and x̅₃=0.21 were realized; however, growth was performed on 2″ diameter patterned GaN/sapphire templates. All given compositions and thicknesses originate from planar single-layer calibration samples as determined by XRD and in-situ spectrometry using a LayTec EpiTT in-situ growth monitoring system. The determination of the compositions and thicknesses of the non-planar samples is discussed below.

Optical microscopy was utilized to determine the formation and density of cracks. Therefore, for every growth thickness and composition, three complete mesas of every width and gap combination were inspected. XRD reciprocal space maps (RSMs) near the (10-15)_{GaN} diffraction peak were measured to determine the composition and strain state. Secondary electron microscopy (SEM) at an acceleration voltage of 3 kV and a beam current on 20 μA as well as AFM in contact mode were utilized to determine the local microstructure and surface morphology. Additionally, cathodoluminescence (CL) measurements were performed at room temperature in an SEM in order to determine the optical properties of the SLs and allow for analysis of the local Al mole fraction distribution over the NPG mesa structures. The acceleration voltage and beam current were kept constant at 5 kV and 2 nA, respectively. The generated light from the electron beam and sample interaction was collimated with a parabolic mirror, then diffracted by a 2400 l/mm ruled grating in a Czerny-Turner spectrometer and collected by a GaAs photomultiplier-tube (PMT) detector. CL spectra were measured with a wavelength resolution of 0.5 nm at room temperature. Monochromatic CL images were acquired by fixing the grating at specific wavelengths.

Results and Discussion

Sample series 1 was inspected after every 500 nm of overgrowth by optical microscopy in order to determine crack formation on the mesa regions. It was found that crack formation occurred in two steps: 1) cracking perpendicular to the etched mesa stripe, i.e., along the shortest possible connection between two trenches—these cracks were parallel to [11-20]_{GaN} and indicated as an “(x)” in Table 1—and 2) Formation of a crack network on the mesa with all cracks oriented in <11-20>_{GaN}. Crack networks are indicated as an “x” in Table 1. The formation of the first cracks perpendicular to the mesa stripe orientation was most likely caused by an anisotropic strain distribution along the mesa as material can relax towards the mesa edges but was limited in relaxation along the mesa stripe. In addition, the following dependencies on the degree of cracking were found:

Influence of Gap, g, in Between Mesas:

The gap, g, between two mesa structures had no significant influence on the formation of cracks within the investigated range 10 μm<g<200 μm. However, for the smallest gap of 10 μm and relatively thick overgrowth layer thickness coalescence of adjacent mesas was observed, which was insignificant. Therefore, in the following, the mesa gap dependence was not further studied and typically chosen to be g=50 μm or g=100 μm.

Influence of Mesa Etch Depth, d:

The variation of the etching depth, d, of the mesas showed an earlier onset of cracking and crack network formation for shallow-etched mesas. Additionally, it was observed that cracks which are perpendicular to the mesa stripe continued in the trench region (alternatively cracks in the trench region progress into the NPG mesa structures). The NPG AlₓGa₁₋ₓN layer structure was also deposited in the trench regions. This led to the assumption that shallow etching did not allow for lateral strain relaxation as the mesa and trench regions were still coupled or influencing each other due to the relatively small difference in the height of the two growth regions.

Influence of NPG Thickness, t.

Iteratively increasing the overgrowth thickness from t=500 nm up to t=3500 nm resulted in an increasing density of cracks on the mesa surface as well as the formation of a crack network. This was to be expected as the strain accumulates and led to cracking after exceeding the critical layer thickness.

Influence of Average Aluminum Composition, x̅:

The variation of the average Al mole fraction, x̅, in the SL structures showed an earlier onset of cracking with increasing Al mole fraction as the accumulated strain was larger for higher Al mole fractions and thus reduced the critical layer thickness (not shown in Table 1).

Influence of Mesa Width, w:

The mesa width, w, was found to have a significant influence on layer cracking. With smaller mesa width, the layers remained crack-free even for SLs with high average Al mole fractions (up to x̅₃=0.21) and large total overgrowth thicknesses. This behavior could be explained by lateral strain relaxation towards the mesa edges, i.e., the sidewalls, allowing for a change in lattice constant. It was significant that the strain relaxation into one direction, e.g., [11-20]_{GaN} was sufficient to also avoid crack formation along the perpendicular direction of the mesa when the thickness, t, and the average alloy composition, x̅, were small enough. Exemplarily, an overview of the crack formation of a Al_{0.16}Ga_{0.84}N-SL grown on different mesa structures is given in Table 1.

To get a better understanding of the structural, morphological, and optical properties of the NPG AlGaN-SL, sample series 2 was grown including three 1500 nm thick AlGaN-SL samples with an average composition of x̅₁=0.11, x̅₂=0.16, and x̅₃=0.21 which were grown continuously on 2700 nm high mesas. The crack formation was shifted to larger mesa sizes in comparison to sample series 1, which could have been caused by a reduced stress origination from the multiple thermal cycles which were applied for the iterative growth. Crack-free 1500 nm thick SLs growth on NPG mesas were observed for AlₓGa₁₋ₓN-SLs having x̅₁=0.11 and x̅₂=0.16 up to 200 μm mesa widths, and for x̅₃=0.21 up to 50 μm mesa width.

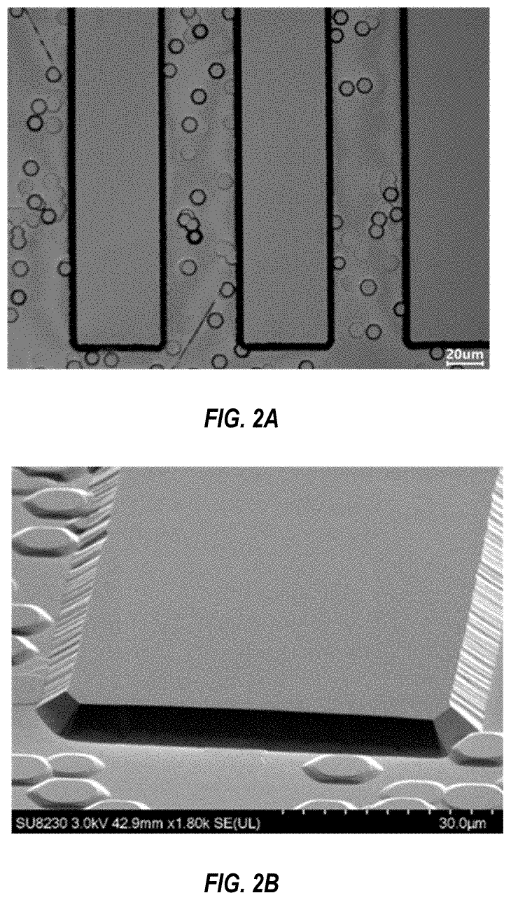

FIGS. 2A-B show exemplarily the surface of a 1500 nm thick NPG AlGaN-SL (w=50 μm, g=50 μm) series 2 sample with an average composition of x̅₂=0.16 grown on a mesa with an etch depth of d=2700 nm. In FIG. 2A, the top view light microscopy image revealed a crack-free mesa with no visible surface features at this magnification. In between the individual mesas, hexagonal structures as well as cracks were visible. The hexagonal structures likely originate from the pits at the GaN/sapphire interface (compare to FIG. 1A)) and have a density of approximately 1×10⁶ cm⁻². Furthermore, the layer cracking in between the mesa structures (see FIG. 2A) indicates that the critical layer thickness was exceeded for planar growth. The SEM image in FIG. 2B shows the formation of three {1-101}_{GaN} facets [15] at the end of the mesa stripe as well as a zig-zag pattern at the long side of the mesa (virtual {11-22}_{GaN} composed of zig-zag-aligned {1-101 }_{GaN} facets) [15] due to the roughness of the ICP-etched GaN mesa sidewalls.

TABLE 1
Overview of the crack formation for iteratively grown Al_{0.16}Ga_{0.84}N—SL
(x̅₂ = 0.16) for various etch depths d, overgrowth thicknesses, t, and
mesa width, w. “(x)” indicates first crack appearance on the mesa
stripes. The formation of a crack network on the mesa surface is
indicated by an “x”.

| | | | NPG thickness t (nm) | | | | | | |
|---|---|---|---|---|---|---|---|---|---|
| x̅₂ = 0.16 | | | 500 | 1000 | 1500 | 2000 | 2500 | 3000 | 3500 |
| etch | mesa | 10 | (x) | (x) | (x) | (x) | x | x | x |
| depth | width w | 20 | (x) | (x) | (x) | x | x | x | x |
| d = | (μm) | 50 | (x) | (x) | x | x | x | x | x |
| 500 nm | | 100 | (x) | x | x | x | x | x | x |
| | | 200 | x | x | x | x | x | x | x |
| etch | mesa | 10 | | | | | | x | x |
| depth | width w | 20 | | | | | (x) | x | x |
| d = | (μm) | 50 | | (x) | (x) | (x) | (x) | x | x |
| 1500 nm | | 100 | | x | x | x | x | x | x |
| | | 200 | x | x | x | x | x | x | x |
| etch | mesa | 10 | | | | (x) | (x) | (x) | (x) |
| depth | width w | 20 | | | | (x) | (x) | (x) | (x) |
| d = | (μm) | 50 | | | | (x) | (x) | (x) | (x) |
| 2700 nm | | 100 | | x | x | x | x | x | x |
| | | 200 | x | x | x | x | x | x | x |

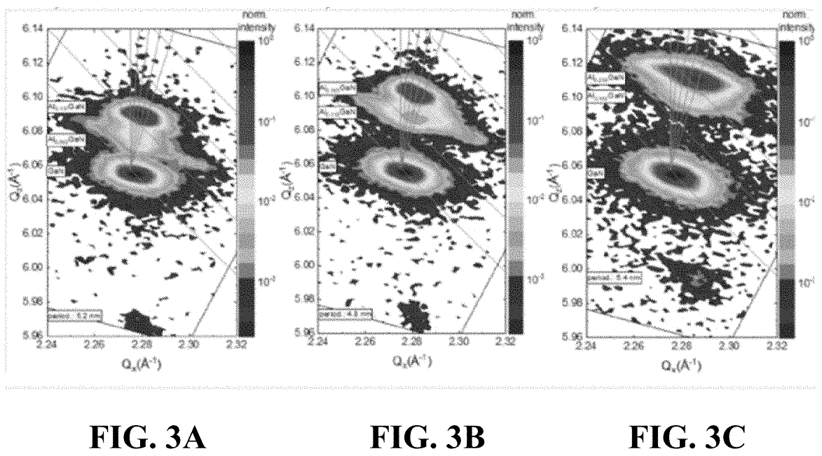

FIGS. 3A-C show XRD reciprocal space maps near the (10-15)_{GaN} reflex for AlGaN-SLs with average composition of a) x̅₁=0.11, b) x̅₂=0.16, and c) x̅₃=0.21 (target composition based on planar single layer calibration). The measured area of the X-ray beam was approximately 10 mm×2 mm, thus the lattice information (i.e., composition and strain state) were collected from both the mesa structures of all dimensions as well as the trench region. Thus, no unambiguous correlation to the individual regions was possible. The following conclusions were drawn. For all NPG AlₓGa₁₋ₓN-SLs two visible XRD reflexes were observed corresponding to average Al compositions of x̅₁ₐ=0.117 and x̅_{1b}=0.062, x̅₂ₐ=0.165 and x̅_{2b}=0.118, as well as x̅₃ₐ=0.216 and x̅_{3b}=0.182 with increasing average target Al composition x̅₁=0.11, x̅₂=0.16, and x̅₃=0.21, respectively. With increasing composition, the strain state of both reflexes moved towards the unstrained lattice position, i.e., the material relaxes. Even though the mesa and trench regions were not resolved with the XRD RSMs, this can explained by a lateral relaxation of the NPG on the mesa as well as strain relaxation by cracking in between the mesa structures. Raman mapping can be used to clarify the local strain distribution. Additionally, in order to understand the appearance of two AlGaN reflexes, CL investigations were performed.

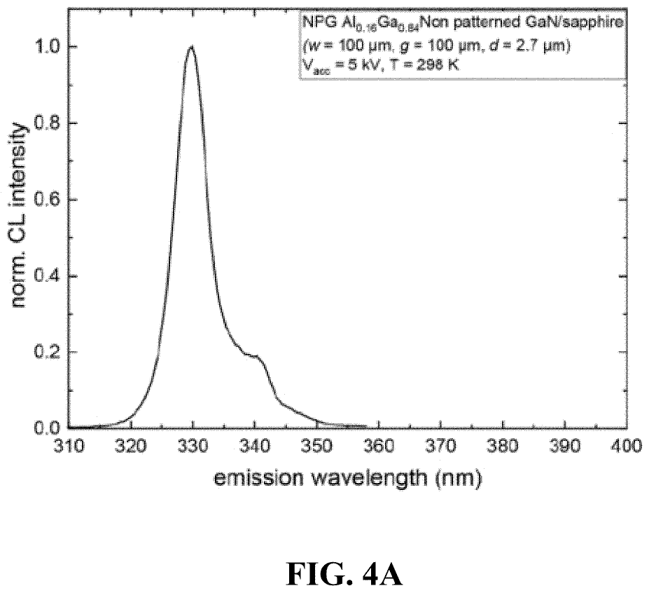

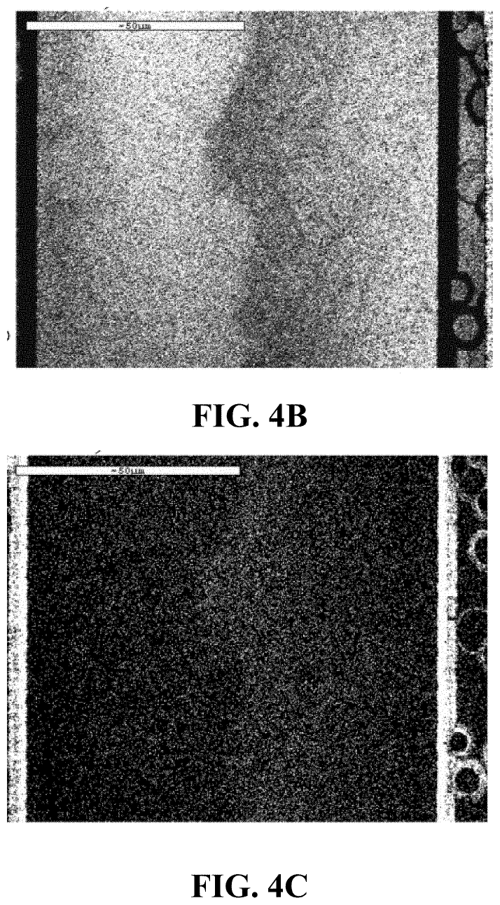

FIGS. 4A-C show exemplarily the mean CL spectrum (298 K) of an NPG Al_{0.16}Ga_{0.84}N-SL on a mesa with dimension l=2 mm, w=100 g=100 and d=2.7 Two different peak emission contributions in the spectrum at λ₂ₐ=331 nm and λ_{2b}=340 nm can be seen. The local origin of the emission band was determined by measuring monochromatic CL intensity maps. The emission at 331 nm originates from the mesa surface as well as the trench region, as shown in FIG. 4B, whereas the emission at 340 nm, in FIG. 4C, originates mainly from the semipolar {1-101 }_{GaN} and {11-22 }_{GaN} mesa sidewalls. Therefore, the lower Al mole fraction composition identified within the XRD RSM was assigned to the semipolar sidewalls and the higher Al mole fraction was assigned to the mesa and trench regions.

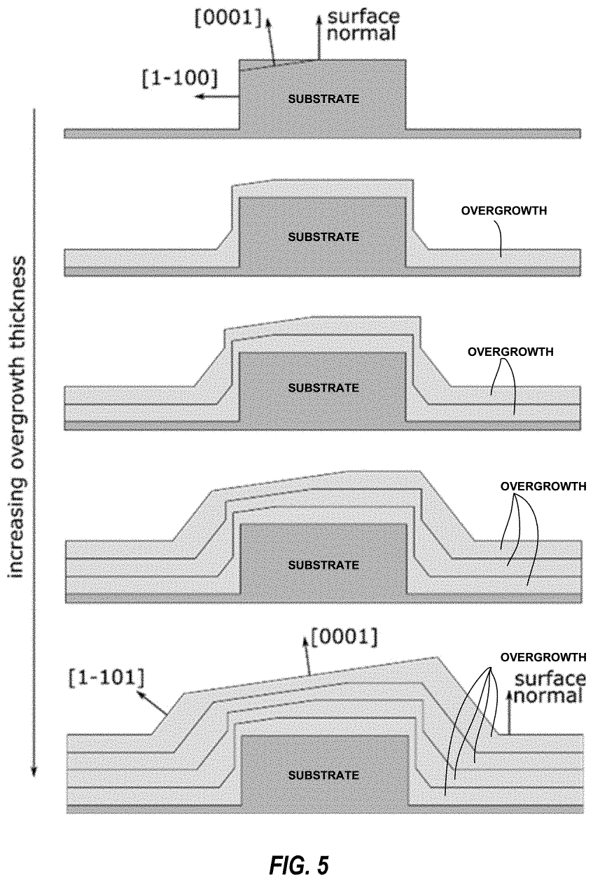

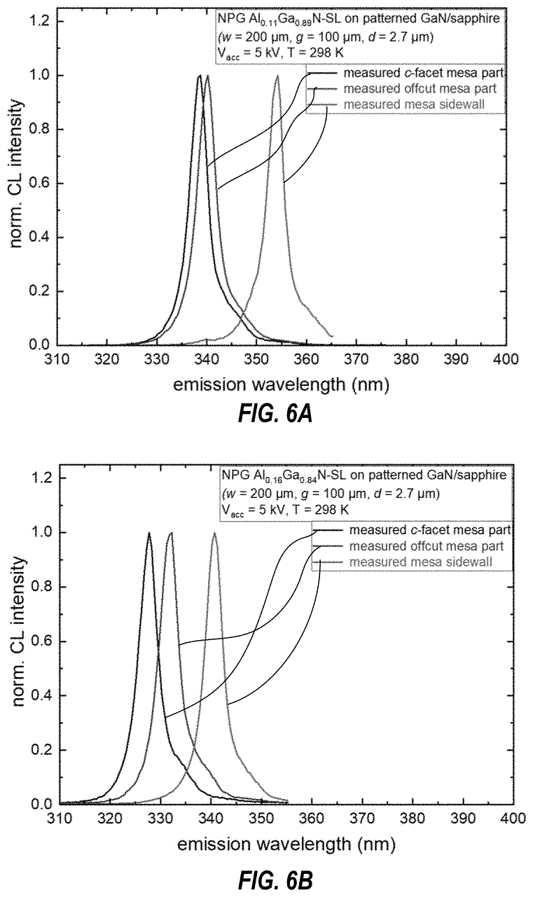

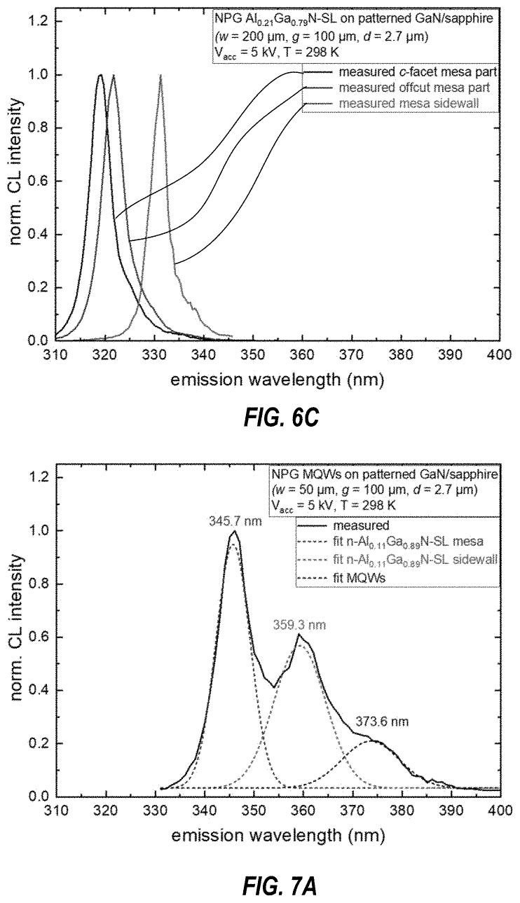

In addition to the Al mole fraction difference between the mesa and the sidewalls, a contrast in the peak intensity of the monochromatic images around the center of the 100 wide mesa was seen. Supersaturating the contrast of low magnification large field of depth in optical microscopy images using differential interference contrast revealed a ridge-like surface feature at this position. Measuring different mesa sizes revealed that the ridge-like feature is always located at the same distance of the same side of the mesa. Detailed analysis of sample series 1 also showed the ridge-like feature which moved cross the mesa with increasing growth thickness. Measuring the step profile revealed a tilt angle between the two sides of the ridge of ˜0.25° which coincided with the sapphire offcut. Furthermore, AFM images showed step flow morphology corresponding the offcut direction on one side of the ridge-like structure whereas the other side did not show any preferential step flow morphology. From these data, it was concluded that starting from the mesa edge an exact c-facet was forming which increased in lateral dimension during overgrowth. The lateral movement of this c-facet was ·50 μm per 1500 nm overgrowth thickness at an offcut angle of 0.25° and would eventually cover the entire mesa dependent on overgrowth thickness, offcut angle, and mesa width. Additionally, the composition of the overgrown AlGaN could influence the lateral movement of the c-facet due to a change of the adatom mobility. A schematic diagram of the overgrowth and formation of the c-facet is shown in FIG. 5. [66] CL spectra measured in spot mode on the two sides of the ridge-like feature, i.e., on the c-facet mesa region, the offcut mesa region, and the semipolar side walls are shown in FIGS. 6A-C for NPG AlₓGa₁₋ₓN-SLs with average composition of a) x̅₁=0.11, b) x̅₂=0.16, and c) x̅₃=0.21. As observed before, the semipolar side wall emission had the longest emission wavelength and thus lowest Al mole fraction due to the larger Ga adatom mobility and preferential incorporation on step edges. Similarly, the emission wavelength measured on the offcut mesa region showed a slightly longer emission wavelength and thus a lower Al mole fraction in comparison to the c-facet region of the mesa which could be attributed to a higher Ga adatom mobility and preferential incorporation at step edges, which are provided by the step flow morphology on the offcut mesa surface.

The emission wavelengths on the c-facet mesa part (λₐ₁), offcut mesa part (λₐ₂), and the mesa sidewall (λ_{b}) with their respective calculated Al mole fractions (assuming Vegard's law and E_{AlN}=6.28 eV, [18, 19] E_{GaN}=3.42 eV [18, 19] and b=1 eV [20, 21] without consideration of confinement in the SL wells but assuming single layer emission) are in good agreement to the observed Al mole fractions as determined by XRD as summarized in Table 2. As the XRD was averaging over a large area including trench regions and wide mesas, the main contribution was related to the offcut mesa part (and offcut trench part). The larger difference in the XRD and CL Al mole fraction determination of the sidewalls of all NPG AlₓGa₁₋ₓN-SLs could be caused by the difference in the anisotropic strain of the semipolar sidewalls as well as a slightly different SL periodicity due to change in the growth rate and thus, a different emission energy.

TABLE 2
CL emission wavelength (λₐ₁, λₐ₂, λ_{b}) of the c-facet mesa part,
the offcut mesa part, and the mesa side wall as well as calculated AlₓGa₁₋ₓN
composition (x̅ₐ, x̅_{b}) from CL emission wavelength and as determined by XRD
RSM for samples with average target composition x̅₁ = 0.11,
x̅₂ = 0.16, and x̅₃ = 0.21.

| | c-facet mesa part | | offcut mesa part | | | Mesa sidewall | | |
|---|---|---|---|---|---|---|---|---|
| | CL λₐ₁ | | CL λₐ₂ | | mesa | CL λ_{b} | | |
| | (nm) | CL x̅ₐ₁ | (nm) | CL x̅ₐ₂ | XRD x̅ₐ | (nm) | CL x̅_{b} | XRD x̅_{b} |
| x̅₁ = 0.11 | 338.5 | 0.130 | 340.0 | 0.121 | 0.117 | 354.0 | 0.038 | 0.062 |
| x̅₂ = 0.16 | 327.7 | 0.193 | 331.8 | 0.169 | 0.165 | 340.7 | 0.117 | 0.118 |
| x̅₃ = 0.21 | 319.1 | 0.244 | 321.6 | 0.229 | 0.216 | 331.0 | 17.4 | 0.182 |

Finally, MQW heterostructures and full laser diode heterostructures designed for emission at ˜370 nm were deposited on NPG GaN/sapphire templates. The heterostructures comprised a 500-nm-thick GaN n-type buffer, a 600 nm thick Al_{0.11}Ga_{0.89}N:Si-SL (5 nm period) n-side cladding, a 150 nm thick Al_{0.06}Ga_{0.94}N:Si n-side waveguide, a 30 nm thick Al_{0.09}Ga_{0.91}N first barrier, and a two-fold 3 nm/9 nm thick In_{0.02}Ga_{0.98}N/Al_{0.09}Ga_{0.91}N MQW active region. The MQW heterostructure was capped with 20 nm of undoped Al_{0.3}Ga_{0.7}N for a total AlGaN layer thickness of ˜820 nm. The growth of the full laser diode heterostructure was continued with a 10 nm thick Al_{0.3}Ga_{0.7}N:Mg electron blocking layer (EBL), a 150 nm thick Al_{0.06}Ga_{0.94}N:Mg p-side waveguide, a 500 nm thick Al_{0.11}Ga_{0.89}N:Mg-SL (5 nm period) p-side cladding, and a 10 nm thick GaN:Mg p-contact layer for a total AlGaN layer thickness of ˜1470 nm, much larger than the critical layer thickness for these materials. The mesa width was chosen to be w<10 μm in order to allow the c-facet to cover the entire mesa and minimize Al mole fraction inhomogeneities across the mesa.

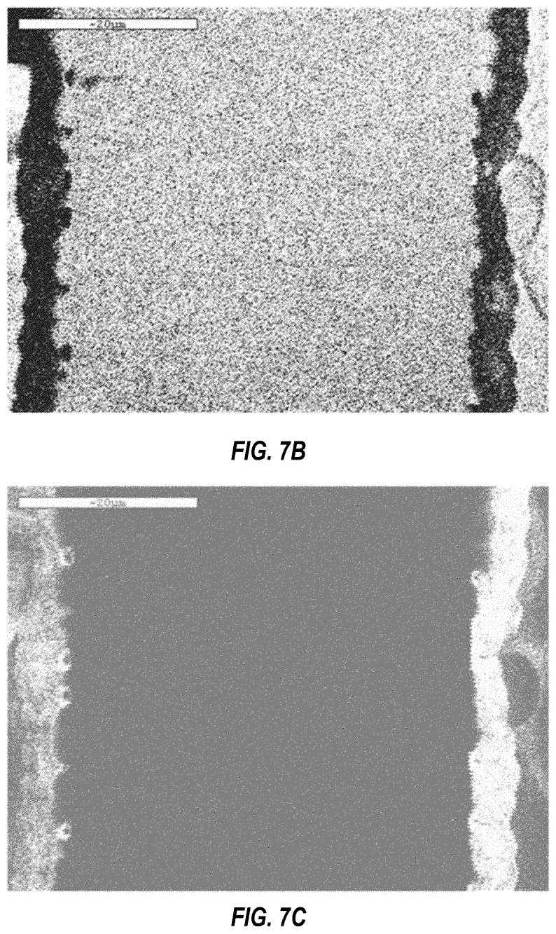

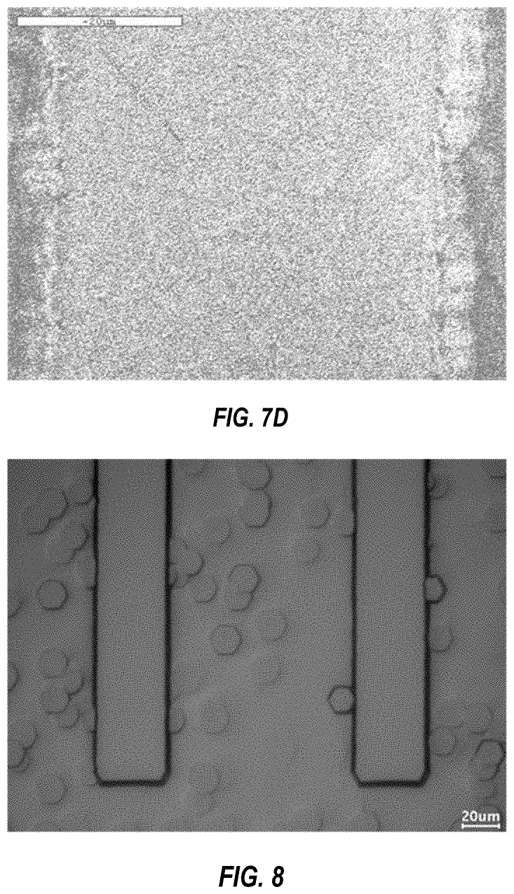

FIG. 7A shows a room temperature CL spectrum of an NPG MQW heterostructure grown on a mesa structure with dimensions l=2 mm, w=50 μm, g=100 and d=2.7 The three spectral contributions correspond to the AlₓGa₁₋ₓN-SL on the mesa and the side walls as well as the MQW emission from the mesa, respectively as shown in the monochromatic CL maps in FIG. 7B for 345.7 nm, FIG. 7C for 359.3 nm, and FIG. 7D for 373.6 nm. There was no separation into a c-facet mesa part and offcut mesa part visible due to the narrow mesa width and consequently the c-facet already covering the entire mesa width. Therefore, the MQW emission at 373.6 nm was homogeneous. The emission wavelength of the AlₓGa₁₋ₓN-SL was slightly longer in comparison to the studies presented earlier which was attributed to shifting reactor conditions over time.

FIG. 8 shows an optical microscopy image of a full NPG laser diode heterostructure grown on a GaN/sapphire mesa with dimensions l=2 mm, w=30 μm, g=100 μm, and d=2.7 μm. Even though the entire heterostructure was nearly 1.5 μm thick utilizing n- and p-doped Al_{0.10}Ga_{0.90}N-SL cladding layers with x̅=0.10, a SL period of 5 nm, and a total thickness ˜1μm, plus n- and p-Al_{0.05}Ga_{0.95}N waveguide layers with a total thickness ˜270 nm, no cracks were observed on the mesas which demonstrated the suitability of the non-planar growth approach for these LD heterostructures. However, some cracks were observed between the mesas where the conventional planar growth occurs.

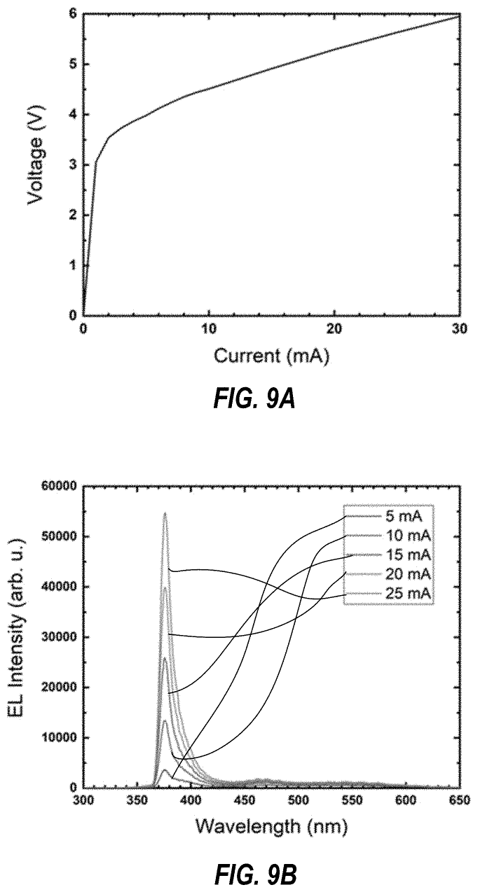

To evaluate the electrical and electroluminescence (EL) properties of these materials, the NPG LD heterostructure shown in FIG. 8 were fabricated into stripe-geometry devices along the [11-20]GaN with ICP etched mesa widths of 10 and 30 μm. Metal stacks of Ti/Al/Ti/Au and Ni/Ag/Ni/Au were utilized to form ohmic contacts for n- and p-type layers, respectively. The LD devices were then cleaved via a laser scribing technique to form { 10-10}GaN facets on both ends of the stripes. The I-V characteristics of some of these stripe-mesa LD devices were measured with probe contacts without heat sinking. For instance, a LD stripe with 30 μm mesa width and an ˜1000 μm long cavity exhibits a turn on voltage below 3V as shown in FIG. 9A. EL spectra at 300K were collected from one cleaved edge via optical fiber for different DC injection currents as shown in FIG. 9B. The emission peak wavelength was 376.8nm with a FWHM of ˜13 nm under injection current of 25 mA. These results verified that the normal doping and p-n junction behavior for NPG heterostructures was relatively unaffected by the mesa overgrowth process.

In summary, this examples showed a non-planar growth approach which allows for crack-free deposition of relatively high Al mole fraction Al,Gai,N and relatively thick heteroepitaxial layers on mesas fabricated on GaN/sapphire templates. The gap between the mesas, the mesa etch depth, and the mesa width as well as the Al mole fraction and thickness of the NPG AlₓGa₁₋ₓN layers was studied systematically showing that limiting the mesa size in one dimension was sufficient to avoid surface crack formation for Al mole fractions and thicknesses beyond the limits of the conventional critical layer thickness of AlGaN planar growth on GaN. Cathodoluminescence studies revealed the formation of an exact on-axis c-facet on the mesa which moves across the mesa with increasing NPG thickness. MQW heterostructures, as well as full AlInGaN laser diode heterostructures designed for emission ˜370 nm, were grown on NPG GaN/sapphire templates demonstrating the suitability of this approach for practical applications. This approach can also be extended to NPG growth on bulk GaN substrates as well as other tensile-strained semiconductor systems.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way.

What is claimed is:

1. A method of fabricating a semiconductor device, comprising:
providing a substrate, the substate comprising a base layer and two or more planar heteroepitaxial layers deposited on the base layer, the two or more heteroepitaxial layers comprising a first epitaxial layer having a first lattice constant and a second epitaxial layer having a second lattice constant different than the first lattice constant;
etching the substrate to form one or more mesas; and
depositing one or more non-planar overgrowth layers on the etched substrate.

2. The method of claim 1, wherein the base layer of the substrate has a nominal offcut angle of between about 0.0 and ±4.0 degrees.

3. The method of claim 1, wherein the base layer comprises sapphire, GaN, AN, Si, GaAs, InP, InGaAs, and/or Ge.

4. The method of claim 1, wherein the two or more heteroepitaxial layers comprise III-V semiconductor materials.

5. The method of claim 4, wherein the two or more heteroepitaxial layers comprise GaN.

6. The method of claim 1, wherein providing the substrate comprises:
providing the base layer; and
epitaxially growing the two or more planar heteroepitaxial layers on the base layer.

7. The method of claim 1, wherein etching the substrate to form the one or more mesas, comprises:
depositing a mask over the substrate;
patterning the mask to remove portions of the mask using photolithography; and
etching the non-masked portions of the substrate to form the one or more mesas.

8. The method of claim 1, wherein the one or more mesas comprise at least a first mesa having a length to width ratio of between about 1:1 and 500:1.

9. The method of claim 1, wherein depositing the one or more non-planar overgrowth layers decreases a tensile strain on the two or more heteroepitaxial layers.

10. The method of claim 1, wherein the one or more non-planar overgrowth layers are epitaxially grown.

11. The method of claim 1, wherein the one or more non-planar overgrowth layers are superlattices.

12. The method of claim 1, wherein the one or more non-planar overgrowth layers comprise one or more materials having the formula of AlₓGa₁₋ₓN and/or AlₓIn_{y}Ga_{1-y}N.

13. The method of claim 1, wherein the one or more non-planar overgrowth layers comprise a first overgrowth layer comprising a first alloy and a second overgrowth layer comprising a second alloy.

14. A semiconductor device, comprising:
a substrate comprising a base layer and two or more heteroepitaxial layers over the base layer;
one or more mesas formed on the substrate; and
one or more non-planar overgrowth layers deposited over the substrate.

15. The semiconductor device of claim 1, wherein the base layer comprises sapphire.

16. The semiconductor device of claim 1, wherein the two or more heteroepitaxial layers comprise III-V semiconductor materials.

17. The semiconductor device of claim 1, wherein the two or more heteroepitaxial layers comprise GaN.

18. The semiconductor device of claim 1, wherein the one or more mesas comprise at least a first mesa having a length to width ratio of between 5:1 and 500:1.

19. The semiconductor device of claim 1, wherein the one or more non-planar overgrowth layers are superlattices.

20. The semiconductor device of claim 1, wherein the one or more non-planar overgrowth layers comprise one or more materials having the formula of AlₓGa₁₋ₓN.
